(19) United States
(12) Patent Application Publication
(10) Pub. No.: US 2025/0386649 A1
(43) Pub. Date: Dec. 18, 2025

(54) ENCAPSULATABLE MATERIAL FOR DISPLAY DEVICE, ENCAPSULATING MATERIAL, ORGANIC EL DISPLAY, AND LED DISPLAY

(71) Applicant: MITSUI CHEMICALS, INC., Chuo-ku, Tokyo (JP)

(72) Inventors: Kei NAGATA, Fujisawa-shi, Kanagawa (JP); Yuji MIZOBE, Chiba-shi, Chiba (JP)

(73) Assignee: MITSUI CHEMICALS, INC., Chuo-ku, Tokyo (JP)

(21) Appl. No.: 18/878,739

(22) PCT Filed: Jul. 20, 2023
(86) PCT No.: PCT/JP2023/026579

§ 371 Date: Dec. 24, 2024

(30) Foreign Application Priority Data
Jul. 26, 2022 (JP) 2022-118463

(51) Int. Cl. H10H 29/854; C08G 59/32; C08K 3/30; H10K 59/80

(52) U.S. Cl. CPC H10H 29/854; C08G 59/3281; C08K 3/30; H10K 59/873

(57) ABSTRACT

An encapsulatable material for a display device includes an epoxy resin, a thermal acid initiator, and a phosphor. The amount of the fluorine ions measured by a predetermined test is 100 ppm or less, or the thermal acid initiator is a quaternary ammonium salt having B(C₆F₅)₄— as the counter anion.

### CROSS-REFERENCE TO RELATED APPLICATIONS

This application is a U.S. National Stage of International Application No. PCT/JP2023/026579, filed on Jul. 20, 2023, which in turn claims priority to Japanese Application No. 2022-118463, filed on Jul. 26, 2022, the entire contents of which is incorporated herein by reference.

### TECHNICAL FIELD

The present invention relates to an encapsulatable material for a display device, an encapsulating material, an organic EL display, and an LED display.

### BACKGROUND ART

In recent years, for example, an organic EL display has been known as an image display device including an optical element. In such an image display device, the optical element is encapsulated by the encapsulating layer to suppress the deterioration of the optical element caused by, for example, the moisture in the atmosphere.

The encapsulating layer is formed, for example, by embedding an optical element in an encapsulatable material for a display device and then curing the encapsulatable material for a display device.

As such an encapsulatable material for a display device, for example, an encapsulatable material for an image display device containing an epoxy resin and a thermal cationic curing agent has been proposed (for example, see Patent Document 1).

### CITATION LIST

### Patent Document

Patent Document 1: WO2021/024616 Pamphlet

### SUMMARY OF THE INVENTION

### Problem to be Solved by the Invention

Meanwhile, to represent the color on the screen, a color filter is provided in the image display device. From the viewpoint of miniaturization, it is considered to blend a phosphor into the encapsulatable material for a display device instead of the color filter.

However, a cured product of the encapsulatable material for an image display device containing a phosphor has a problem of discoloration under high temperature and high humidity.

The present invention provides an encapsulatable material for a display device which suppresses discoloration at high temperature and high humidity, an encapsulating material containing a cured product of the encapsulatable material for a display device, an organic EL display containing the encapsulating material, and an LED display containing the encapsulating material.

### Means for Solving the Problem

The present invention [1] includes an encapsulatable material for a display device including: an epoxy resin; a thermal acid initiator; and a phosphor, wherein an amount of fluorine ions measured by the following test is 100 ppm or less.

### <Test>

The Components other than the phosphor are blended to prepare a mixture. Then, the mixture having a thickness of 100 μm is applied to a polyethylene terephthalate film, and cured to obtain a cured product. Then, the cured product is peeled from the polyethylene terephthalate film, and the cured product is put into a heat-resistant container made of polytetrafluoroethylene, and 5 mL of ultrapure water is also added thereto, and the heat-resistant container is sealed. Then, the heat-resistant container is placed in a dryer and heated at 100° C. for 20 hours to obtain extracted water extracted from the cured product. The heat-resistant container is then cooled to 25° C., and the extracted water is collected. Then, the extracted water is diluted, and the fluorine ions of the extracted water is quantitatively determined by an ion chromatography method.

The present invention [2] includes the encapsulatable material for a display device described in the above-described [1], wherein the phosphor is a sulfur-containing phosphor.

The present invention [3] includes the encapsulatable material for a display device described in the above-described [1] or [2], wherein the thermal acid initiator contains a fluorine atom.

The present invention [4] includes the encapsulatable material for a display device described in any one of the above-described [1] to [3], wherein the thermal acid initiator is a quaternary ammonium salt having B(C₆F₅)₄— as a counter anion.

The present invention [5] includes the encapsulatable material for a display device described in any one of the above-described [1] to [4], further including: an antioxidant.

The present invention [6] includes the encapsulatable material for a display device described in the above-described [5], wherein the antioxidant includes a hindered phenol antioxidant and a phosphite antioxidant.

The present invention [7] includes an encapsulatable material for a display device including: an epoxy resin; a thermal acid initiator; and a phosphor, wherein the thermal acid initiator is a quaternary ammonium salt having B(C₆F₅)₄— as a counter anion.

The present invention [8] includes the encapsulatable material for a display device described in the above-described [7], further including: an antioxidant.

The present invention [9] includes the encapsulatable material for a display device described in any one of the above-described [1] to [8], wherein a color difference in the following color difference test is 1.1 or less.

Color difference test: The encapsulatable material for a display device is applied to a glass plate to form a coating film. Then, the coating film is heated at 120° C. for 60 minutes, and the coating film is cured to obtain a cured product having a thickness of 100 μm. Then, an a* (initial stage) of the cured product is measured using a color difference meter. The cured product is then stored at 85° C. and 85% humidity for 7 days, and an a* (after 7 days) is measured. (|a* (initial stage)|−|a* (after 7 days)|) is determined as the color difference.

The present invention [10] includes an encapsulating material including: a cured product of the encapsulatable material for a display device described in any one of the above-described [1] to [9].

The present invention [11] includes an organic EL display including: the encapsulating material described in the above-described [10].

The present invention [12] includes an LED display including the encapsulating material described in the above-described [10].

### Effects of the Invention

In the encapsulatable material for a display device of the present invention, the amount of fluorine ions measured by a predetermined test is 100 ppm or less, or the thermal acid initiator is a quaternary ammonium salt having B(C₆F₅)₄⁻ as the counter anion. Therefore, it is possible to suppress the discoloration of the cured product under high temperature and high humidity.

The encapsulating material of the present invention includes a cured product of the encapsulatable material for a display device of the present invention. Therefore, discoloration can be suppressed under high temperature and high humidity.

The organic EL display of the present invention includes the encapsulating material of the present invention. Therefore, discoloration can be suppressed under high temperature and high humidity.

The LED display of the present invention includes the encapsulating material of the present invention. Therefore, discoloration can be suppressed under high temperature and high humidity.

### DESCRIPTION OF THE EMBODIMENTS

### 1. First Invention

In the first invention, the encapsulatable material for a display device contains an epoxy resin, a thermal acid initiator, and a phosphor. Furthermore, in the encapsulatable material for a display device, the amount of fluorine ions to be described later is a predetermined value or less.

### <Epoxy Resin>

Examples of the epoxy resin include a siloxane skeleton-free epoxy resin and a siloxane skeleton-containing epoxy resin.

### [Siloxane Skeleton-Free Epoxy Resin]

The siloxane skeleton-free epoxy resin does not include a siloxane skeleton and has an epoxy group.

Examples of the siloxane skeleton-free epoxy resin include a siloxane skeleton-free aromatic epoxy resin, a siloxane skeleton-free alicyclic epoxy resin, and a siloxane skeleton-free aliphatic epoxy resin.

### (Siloxane Skeleton-Free Aromatic Epoxy Resin)

Examples of the siloxane skeleton-free aromatic epoxy resin include bisphenol type epoxy resins (e.g., bisphenol A type epoxy resins and bisphenol F type epoxy resins), novolac type epoxy resins (e.g., phenol novolac type epoxy resins, cresol novolac type epoxy resins, biphenyl novolac type epoxy resins), and modified products thereof (specifically, alkylene oxide adducts (preferably propylene oxide adducts)).

As the siloxane skeleton-free aromatic epoxy resin, a bisphenol type epoxy resin and/or an alkylene oxide adduct of a bisphenol type epoxy resin are/is preferably used. As the siloxane skeleton-free aromatic epoxy resin, more preferably, a bisphenol F type epoxy resin and/or a propylene oxide adduct of a bisphenol A type epoxy resin are/is used. As the siloxane skeleton-free aromatic epoxy resin, a bisphenol F type epoxy resin is even more preferably used.

As the siloxane skeleton-free aromatic epoxy resin, a commercially available product can also be used. Examples of commercially available products of the siloxane skeleton-free aromatic epoxy resin include YL983U (bisphenol F type epoxy resin, manufactured by Mitsubishi Chemical Corporation), and EP-4010S (propylene oxide adduct of bisphenol A type epoxy resin, manufactured by ADEKA CORPORATION).

### (Siloxane Skeleton-Free Alicyclic Epoxy Resin)

Examples of the siloxane skeleton-free alicyclic epoxy resin include a siloxane skeleton-free glycidyl group-containing alicyclic epoxy resin, a siloxane skeleton-free glycidyl ether group-containing alicyclic epoxy resin, and a siloxane skeleton-free epoxycyclo structure-containing epoxy resin.

### ((Siloxane Skeleton-Free Glycidyl Group-Containing Alicyclic Epoxy Resin))

The siloxane skeleton-free glycidyl group-containing alicyclic epoxy resin has, for example, a glycidyl group bonded to an aliphatic ring. Such a siloxane skeleton-free glycidyl group-containing alicyclic epoxy resin is represented, for example, by the following general formula (1).

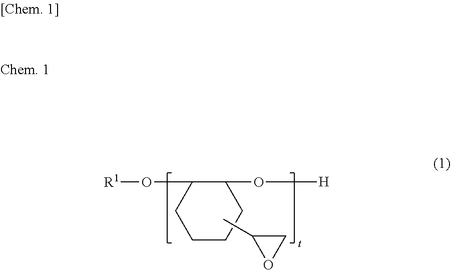

In the formula (1), R¹ represents a monovalent organic group, and 1 represents a degree of polymerization. Furthermore, a substituent such as an alkyl group may be bonded to a carbon atom forming a cyclohexane ring.

Specifically, examples of the siloxane skeleton-free glycidyl group-containing alicyclic epoxy resin represented by the above-described general formula (1) include a 1,2-epoxy-4-(2-oxiranyl)cyclohexane adduct of 2,2-bis(hydroxymethyl)-1-butanol.

As the siloxane skeleton-free glycidyl group-containing alicyclic epoxy resin represented by the above-described general formula (1), a commercially available product can also be used. Examples of commercially available products of the siloxane skeleton-free glycidyl group-containing alicyclic epoxy resin represented by the above-described general formula (1) include EHPE3150 (epoxy equivalent 170 to 190 g/eq., manufactured by Daicel Corporation).

### ((Siloxane Skeleton-Free Glycidyl Ether Group-Containing Alicyclic Epoxy Resin))

The siloxane skeleton-free glycidyl ether group-containing alicyclic epoxy resin has a glycidyl ether unit bonded to an aliphatic ring. Preferably, the siloxane skeleton-free glycidyl ether group-containing alicyclic epoxy resin is a siloxane skeleton-free polyglycidyl ether-containing alicyclic epoxy resin having a plurality of glycidyl ether units bonded to the aliphatic ring.

Examples of the siloxane skeleton-free polyglycidyl ether-containing alicyclic epoxy resin include a siloxane skeleton-free bifunctional type glycidyl ether-containing alicyclic epoxy resin.

Examples of the siloxane skeleton-free bifunctional type glycidyl ether-containing alicyclic epoxy resin include a hydrogenated bisphenol A diglycidyl ether, a hydrogenated bisphenol F diglycidyl ether, and a hexahydrophthalic acid diglycidyl ester. As the siloxane skeleton-free bifunctional type glycidyl ether-containing alicyclic epoxy resin, a hydrogenated bisphenol A diglycidyl ether is preferably used.

As the siloxane skeleton-free glycidyl ether group-containing alicyclic epoxy resin, a commercially available product can also be used. Examples of commercially available products of the siloxane skeleton-free glycidyl ether group-containing alicyclic epoxy resin include YX8000 (hydrogenated bisphenol A diglycidyl ether, manufactured by Mitsubishi Chemical Corporation).

### ((Siloxane Skeleton-Free Epoxycyclo Structure-Containing Epoxy Resin))

The siloxane skeleton-free epoxycyclo structure-containing epoxy resin has an epoxycyclo structure having an epoxy group formed of two adjacent carbon atoms forming an aliphatic ring and one oxygen atom bonded to the two carbon atoms.

Examples of the siloxane skeleton-free epoxycyclo structure-containing epoxy resin include a siloxane skeleton-free epoxy cyclohexane structure-containing epoxy resin (hereinafter, referred to as an ECH structure-containing epoxy resin).

Examples of the ECH structure-containing epoxy resin include an epoxy resin having one ECH structure represented by the following chemical formula (2), an epoxy resin having one ECH represented by in the following chemical formula (3), an epoxy resin having two ECH structures represented by the following general formula (4), and modified products thereof.

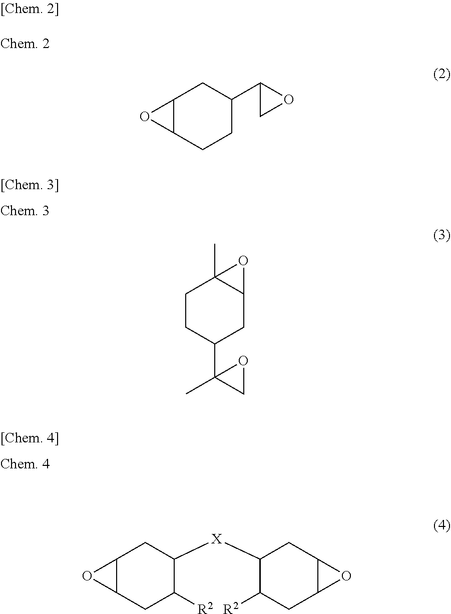

In the formula (4), X represents a linking group (a bivalent group having 1 or more atoms). R² represents one atom or substituent selected from the group consisting of a hydrogen atom, a fluorine atom, an alkyl group, a fluoroalkyl group, an aryl group, a furyl group, and a thienyl group. The two R²s in the formula (4) may be the same as each other or different from each other.

An epoxy resin containing the two ECH structures represented by the above-described general formula (4) (hereinafter, referred to as an ECH structure-containing epoxy resin represented by the general formula (4)) has an ECH structure (epoxy cyclohexyl group) at both terminals of the molecular, and two epoxy cyclohexyl groups are bonded thereto via a linking group. The epoxy cyclohexyl group is a functional group containing a cyclohexane ring and an epoxy group formed of two adjacent carbon atoms forming the cyclohexane ring and one oxygen atom bonded to the two carbon atoms.

Examples of the alkyl group represented by R² in the above-mentioned general formula (4) include, for example, a straight-chain or branched-chain alkyl group having 1 to 6 carbon atom(s) (e.g., a methyl group, an ethyl group, a propyl group, a butyl group, a pentyl group, and a hexyl group).

Examples of the fluoroalkyl group represented by R² in the above-described general formula (4) include a straight-chain or branched-chain fluoroalkyl group having 1 to 6 carbon atom(s) (e.g., a perfluoromethyl group, a perfluoroethyl group, and a perfluoropropyl group).

Examples of the aryl group represented by R² in the above-described general formula (4) include an aryl group having 6 to 18 carbon atoms (e.g., a phenyl group and a naphthyl group).

Examples of the linking group represented by X in the above-described general formula (4) include, for example, an oxygen atom, a sulfur atom, a bivalent hydrocarbon group, a polyoxyalkylene group, a carbonyl group, an ether group, a thioether group, an ester group, a carbonate group, an amide group, and a group in which these groups are linked.

Examples of the bivalent hydrocarbon group include a straight-chain or branched-chain alkylene group having 1 to 20 carbon atom(s) (e.g., a methylene group, a methylmethylene group, a dimethylmethylene group, an ethylene group, a propylene group, a trimethylene group, and a butylene group), a straight-chain or branched-chain unsaturated hydrocarbon group having 1 to 20 carbon atom(s) (e.g., a propenylene group, a methylpropenylene group, and a butenylene group).

Examples of the polyoxyalkylene group include a straight-chain or branched-chain polyoxyalkylene group having 1 to 120 carbon atom(s) (e.g., a polyoxyethylene group and a polyoxypropylene group).

Specifically, examples of the ECH structure-containing epoxy-resin represented by the general formula (4) include (3,3′,4, 4′-diepoxy)bicyclohexyl, bis(3,4-epoxycyclohexylmethyl)ether, 1,2-bis(3,4-epoxycyclohexan-1-yl)ethane, 2,2-bis(3,4-epoxycyclohexan-1-yl)propane, 3′, 4′-epoxycyclohexylmethyl(3,4-epoxy)cyclohexanecarboxylate, and ε-caprolactone modified 3′, 4′-epoxycyclohexylmethyl 3,4-epoxycyclohexanecarboxylate. As the ECH structure-containing epoxy resin represented by the general formula (4), preferably, 3′, 4′-epoxycyclohexylmethyl(3,4-epoxy)cyclohexanecarboxylate is used.

Furthermore, as the ECH structure-containing epoxy-resin represented by the above-described general formula (4), a commercially available product may be used. Examples of commercially available products of the ECH structure-containing epoxy resin represented by the above-described general formula (4) include celloxide 2021P (3′, 4′-epoxycyclohexylmethyl(3,4-epoxy)cyclohexanecarboxylate) (manufactured by Daicel Corporation).

As the ECH structure-containing epoxy resin, the ECH structure-containing epoxy resin represented by the above-described general formula (4) is preferably used.

Then, as the siloxane skeleton-free alicyclic epoxy resin, preferably, a siloxane skeleton-free glycidyl ether group-containing alicyclic epoxy resin and/or a siloxane skeleton-free epoxycyclo structure-containing epoxy resin are/is used.

### (Siloxane Skeleton-Free Aliphatic Epoxy Resin)

Examples of the siloxane skeleton-free aliphatic epoxy resin include a siloxane skeleton-free bifunctional aliphatic epoxy resin. Examples of the siloxane skeleton-free bifunctional aliphatic epoxy resin include an ethylene glycol diglycidyl ether, a propylene glycol diglycidyl ether, a 1,6-hexanediol diglycidyl ether, and a neopentyl glycol diglycidyl ether.

As the siloxane skeleton-free epoxy resin, preferably, a siloxane skeleton-free aromatic epoxy resin and/or a siloxane skeleton-free alicyclic epoxy resin are/is used.

### [Siloxane Skeleton-Containing Epoxy Resin]

The siloxane skeleton-containing epoxy resin has a siloxane skeleton and an epoxy group in combination.

Examples of the siloxane skeleton-containing epoxy resin include a straight-chain siloxane skeleton-containing epoxy resin, a cyclic siloxane skeleton-containing epoxy resin, and a ladder-like siloxane skeleton-containing epoxy resin.

### (Straight-Chain Siloxane Skeleton-Containing Epoxy Resin)

The straight-chain siloxane skeleton-containing epoxy resin is, for example, a compound represented by the following formula (5).

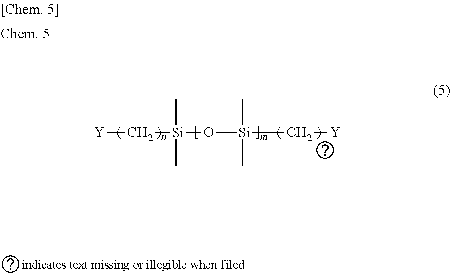

In the above-described formula (5), m represents an integer of 1 or more and 20 or less. Furthermore, in the above-described formula (5), n represents an integer of 1 or more and 10 or less. Furthermore, in the above-described formula (5), o represents an integer of 1 or more and 10 or less. In the above-described formula (5), Y represents an epoxy group or an epoxycyclo group (e.g., an epoxycyclohexane group). Note that, in the above-described formula (5), the two Ys are the same or different from each other.

As the straight-chain siloxane skeleton-containing epoxy resin, preferably, a compound represented by the following formula (6) (a compound in which m represents 1, n represents 2, o represents 2, and two Ys represent an epoxycyclohexane group in the above-described formula (5)) is used.

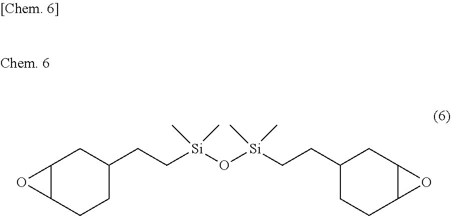 [SMILES: C[Si](C)(CCC1CCC2OC2C1)O[Si](C)(C)CCC1CCC2OC2C1]

Furthermore, a commercially available product may be used as the straight-chain siloxane skeleton-containing epoxy resin. Examples of commercially available products of the straight-chain siloxane skeleton-containing epoxy resin include X-40-2669 (a compound represented by the above-described formula (6), manufactured by Shin-Etsu Chemical Co., Ltd.).

### (Cyclic Siloxane Skeleton-Containing Epoxy Resin)

The cyclic siloxane skeleton-containing epoxy resin has a cyclic siloxane skeleton.

Examples of the cyclic siloxane skeleton include a hexamethylcyclotrisiloxane skeleton (C₆H₁₈O₃Si₃), an octamethylcyclotetrasiloxane skeleton (C₈H₂₄O₄Si₄), and a decamethylcyclopentasiloxane skeleton (C₁₀H₃₀O₅Si₅).

The cyclic siloxane skeleton-containing epoxy resin preferably has an octamethylcyclotetrasiloxane skeleton.

Such a cyclic siloxane skeleton-containing epoxy resin is, for example, a compound represented by the following formula (7).

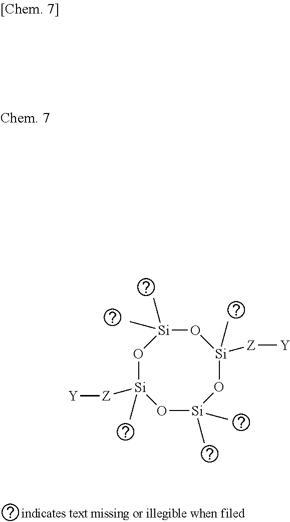

In the above-described formula (7), Z represents a linking group (a bivalent group having 1 or more atom(s)). Examples of the linking group include an alkylene group having 1 to 8 carbon atom(s). Examples of the alkylene group having 1 to 8 carbon atom(s) include, for example, a methylene group, an ethylene group, a propylene group, a butylene group, a pentylene group, a hexylene group, a heptylene group, and an octylene group.

Furthermore, in the above-described formula (7), Y has the same meaning as that of the Y in the above-described formula (5).

Furthermore, in the above-described formula (7), R³ represents a saturated hydrocarbon group or —Z—Y. Examples of the saturated hydrocarbon group include a straight-chain or branched-chain alkyl group having 1 to 6 carbon atom(s) and a cycloalkyl group having 3 to 6 carbon atoms. Examples of the straight-chain or branched-chain alkyl group having 1 to 6 carbon atom(s) include a methyl group, an ethyl group, a propyl group, an isopropyl group, a butyl group, an isobutyl group, a pentyl group, and a hexyl group. Examples of the cycloalkyl group having 3 to 6 carbon atoms include a cyclopentyl group and a cyclohexyl group. In the above-described formula (7), the six R³s are the same or different from each other.

Examples of the cyclic siloxane skeleton-containing epoxy resin include a compound represented by the following formula (8) and/or a compound represented by the following formula (9).

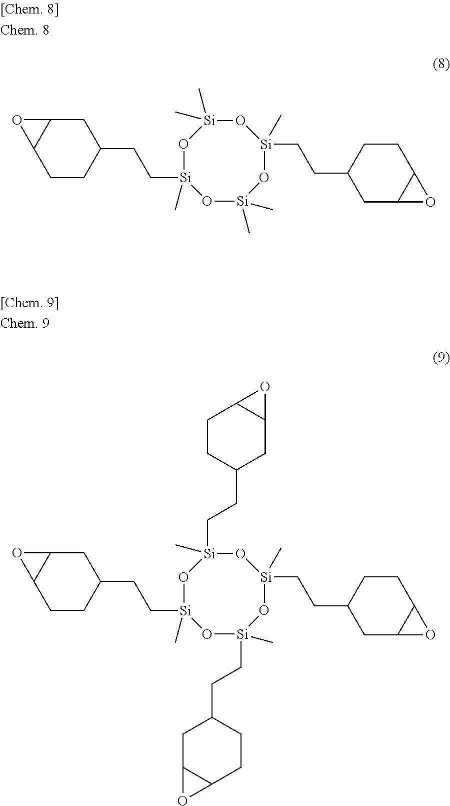 [SMILES: C[Si]1(C)O[Si](C)(CCC2CCC3OC3C2)O[Si](C)(C)O[Si](C)(CCC2CCC3OC3C2)O1 ; C[Si]1(CCC2CCC3OC3C2)O[Si](C)(CCC2CCC3OC3C2)O[Si](C)(CCC2CCC3OC3C2)O[Si](C)(CCC2CCC3OC3C2)O1]

Furthermore, a commercially available product may be used as the cyclic siloxane skeleton-containing epoxy resin. Examples of commercially available products of the cyclic siloxane skeleton-containing epoxy resin include X-40-2678 (a compound represented by the above-described formula (8), manufactured by Shin-Etsu Chemical Co., Ltd.), and KR-470 (a compound represented by the above-described formula (9), manufactured by Shin-Etsu Chemical Co., Ltd.).

### (Ladder-Like Siloxane Skeleton-Containing Epoxy Resin)

The ladder-like siloxane skeleton-containing epoxy resin includes a ladder-like siloxane skeleton.

The ladder-like siloxane skeleton is a 2-dimensional network structure in which a siloxane bond has a ladder-like skeleton as represented by the following formula (10).

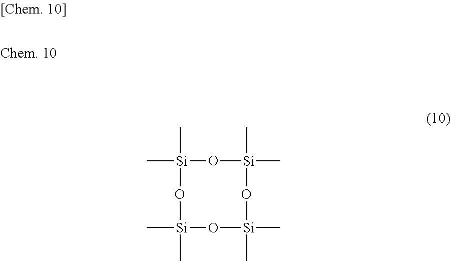

Examples of the ladder-like siloxane skeleton-containing epoxy resin include a compound represented by the following formula (11).

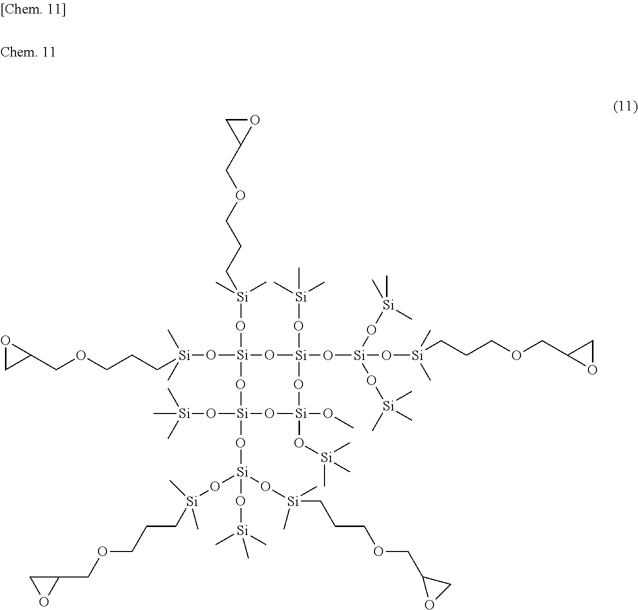 [SMILES: CO[Si]1(O[Si](C)(C)C)O[Si](O[Si](C)(C)C)(O[Si](O[Si](C)(C)C)(O[Si](C)(C)C)O[Si](C)(C)CCCOCC2CO2)O[Si](O[Si](C)(C)CCCOCC2CO2)(O[Si](C)(C)CCCOCC2CO2)O[Si](O[Si](C)(C)C)(O[Si](O[Si](C)(C)C)(O[Si](C)(C)CCCOCC2CO2)O[Si](C)(C)CCCOCC2CO2)O1]

Furthermore, a commercially available product may be used as the ladder-like siloxane skeleton-containing epoxy resin. Examples of commercially available products of the ladder-like siloxane skeleton-containing epoxy resin include YL-9028 (a compound represented by the above-described formula (10), manufactured by Mitsubishi Chemical Corporation).

The weight-average molecular weight of the epoxy resin is, for example, 130 or more, for example, 3000 or less. The weight-average molecular weight (Mw) can be determined by gel permeation chromatography (GPC) using polystyrene as a standard substance.

Furthermore, the epoxy equivalent in the epoxy resin is, for example, 100 g/eq. or more, for example, 1000 g/eq. or less. The epoxy equivalent can be measured in conformity with JIS K7236: 2001.

The epoxy resins may be used alone or in combination of two or more.

The content ratio of the epoxy resin is, for example, 20% by mass or more, preferably 30% by mass or more, and, for example, 60% by mass or less with respect to the encapsulatable material for a display device.

### <Thermal Acid Initiator>

The thermal acid initiator is a thermal acid generator which generates an acid by heat.

The thermal acid initiator includes a fluorine atom. The thermal acid initiator is selected so as to set the amount of fluorine ions to be described later to a predetermined value or less.

Examples of such a thermal initiator include, for example, a quaternary ammonium salt having B(C₆F₅)₄— as the counter anion.

Furthermore, a commercially available product may be used as the thermal acid initiator. Examples of commercially available products of the thermal initiator include, for example, CXC-1821 (a quaternary ammonium salt having B(C₆F₅)₄—, manufactured by King industry).

The thermal acid initiators may be used alone or in combination of two or more.

The content ratio of the thermal acid initiator is, for example, 1 part by mass or more, and also, for example, 10 parts by mass or less, preferably 5 parts by mass or less with respect to 100 parts by mass of the epoxy resin.

Furthermore, the content ratio of the thermal acid initiator is, for example, 0.5% by mass or more, and also, for example, 5% by mass or less, preferably 2.5% by mass or less with respect to the encapsulatable material for a display device.

### <Phosphor>

The phosphor has a wavelength conversion function. The phosphor converts, for example, light from an optical element into light of a predetermined wavelength.

Examples of the phosphor include a sulfur-containing phosphor and a sulfur-free phosphor.

Examples of the sulfur-containing phosphor include a sulfur-containing red phosphor, a sulfur-containing green phosphor, a sulfur-containing blue phosphor, and a sulfur-containing yellow phosphor.

Examples of the sulfur-containing red phosphor include (Ca, Sr)S:Eu, (Zn, Cd)(S, Se):Ag, Ba₂ZnS₃:Mn, (Ca₁₋ₓSrₓ)S:Eu, In(0<x<1), and La₂O₂S:Eu.

Examples of the sulfur-containing green phosphor include, for example, (Ca, Sr, Ba) (Al, Ga, In)₂, S₄:Eu, SrS:Tb, and CaS:Ce.

Examples of the sulfur-containing blue phosphor include, for example, SrS:Ce, (Sr, Ca) Ga₂S₄:Ce, BaAl₂S₄:Eu, Ba₂SiS₄:Ce, and Ba₂(Si₁₋ₓAlₓ)S₄:Ce (0<x<1).

Examples of the sulfur-containing yellow phosphor include, for example, CaGa₂S₄:Eu, Sr₂SiS₄:Eu, and CaS:Ce, Eu.

Examples of the sulfur-free phosphor include a sulfur-free yellow phosphor and a sulfur-free red phosphor.

Examples of the sulfur-free yellow phosphor include, for example, Y₃Al₅O₁₂:Ce and Tb₃Al₃O₁₂:Ce.

Examples of the sulfur-free red phosphor include, for example, CaAlSiN₃:Eu and CaSiN₂:Eu.

As the phosphor, a sulfur-containing phosphor is preferably used from the viewpoint of increasing the color purity. As the phosphor, a sulfur-containing green phosphor is more preferably used.

The phosphors may be used alone or in combination of two or more.

The content ratio of the phosphor is, for example, 60 parts by mass or more, preferably 80 parts by mass or more, and also, for example, 150 parts by mass or less, preferably 120 parts by mass or less with respect to the components other than the phosphor (specifically, the epoxy resin, the thermal acid initiator, and another component to be blended if necessary (described later)).

Furthermore, the content ratio of the phosphor is, for example, 40 parts by mass or more, preferably 80 parts by mass or more, and also, for example, 250 parts by mass or less, preferably 180 parts by mass or less, more preferably 130 parts by mass or less with respect to 100 parts by mass of the epoxy resin.

Furthermore, the content ratio of the phosphor is, for example, 40% by mass or more, and also, for example, 60% by mass or less with respect to the encapsulatable material for a display device.

### <Another Component>

The encapsulatable material for a display device contains another component, if necessary.

Examples of the other components include, for example, another cationic polymerization compound and an additive.

### [Another Cationic Polymerization Compound]

The other cationic polymerization compound is a cationic polymerization compound other than epoxy resins, and examples thereof include an oxetane compound.

The oxetane compound contains, for example, 1 or more and 5 or less oxetane rings.

Examples of the oxetane compound include a monofunctional oxetane compound having one oxetane ring, a bifunctional oxetane compound having 2 oxetane rings, and a trifunctional or more oxetane compound having 3 or more oxetane rings.

Examples of the monofunctional oxetane compound include 2-ethylhexyloxetane, 3-ethyl-3-hydroxymethyloxetane, 3-(meta)allyloxymethyl-3-ethyloxetane, (3-ethyl-3-oxetanylmethoxy)methylbenzene, 2-ethylhexyl(3-ethyl-3-oxetanylmethyl)ether, ethyldiethylene glycol(3-ethyl-3-oxetanylmethyl)ether, and 3-cyclohexylmethyl-3-ethyl-oxetane.

Examples of the bifunctional oxetane compound include, for example, 1,4-bis{[(3-ethyl-3-oxetanyl)methoxy]methyl}benzene, 3-ethyl-3{[(3-ethyloxetan-3-yl)methoxy]methyl}oxetane, 1,4-bis[(3-ethyl-3-oxetanyl)methoxy]benzene, 1,3-bis[(3-ethyl-3-oxetanyl)methoxy]benzene, 3,7-bis(3-oxetanyl)-5-oxa-nonane, 1,4-bis[(3-ethyl-3-oxetanylmethoxy)methyl]benzene, 1,2-bis[(3-ethyl-3-oxetanylmethoxy)methyl]ethane, 1,2-bis[(3-ethyl-3-oxetanylmethoxy)methyl]propane, ethylene glycol bis(3-ethyl-3-oxetanylmethyl)ether, and dicyclopentenyl bis(3-ethyl-3-oxetanylmethyl)ether. As the bifunctional oxetane compound, 3-ethyl-3{[(3-ethyloxetane-3-yl)methoxy]methyl}oxetane is preferably used.

As the bifunctional oxetane compound, a commercially available product can also be used. Examples of commercially available products of the bifunctional oxetane compound include ARON OXETANE OXT-221 (3-ethyl-3 {[(3-ethyloxetane-3-yl)methoxy]methyl}oxetane, manufactured by TOAGOSEI CO., LTD.).

Examples of the trifunctional or more oxetane compound include, for example, trimethylolpropane tris(3-ethyl-3-oxetanylmethyl) ether, pentaerythritol tris(3-ethyl-3-oxetanylmethyl) ether, pentaerythritol tetrakis(3-ethyl-3-oxetanylmethyl) ether, and dipentaerythritol pentakis(3-ethyl-3-oxetanylmethyl) ether.

As the oxetane compound, a bifunctional oxetane compound is preferably used.

The other cationic polymerization compounds may be used alone or in combination of two or more.

The content ratio of the other cationic polymerization compound is, for example, 60 parts by mass or more, preferably 80 parts by mass or more, and also, for example, 150 parts by mass or less, preferably 120 parts by mass or less with respect to 100 parts by mass of the epoxy resin.

Furthermore, the content ratio of the other cationic polymerization compound is, for example, 10% by mass or more, and also, for example, 30% by mass or less with respect to the encapsulatable material for a display device.

### [Additives]

Examples of the additive include a tackifier, a photosensitizer, a leveling agent, a coupling agent, a light stabilizer, an antioxidant, a polymerization initiator, an anti-aging agent, a wettability modifier, a surfactant, a plasticizer, an ultraviolet absorber, a preservative, and an antibacterial agent. As the additive, a light stabilizer and/or an antioxidant are/is preferably used from the viewpoint of further suppressing the discoloration of the cured product under high temperature and high humidity. The additives may be used alone or in combination of two or more.

Examples of the light stabilizer include a hindered amine light stabilizer. Examples of the hindered amine-based light stabilizer include, for example, tetrakis(1,2,2,6,6-pentamethyl-4-piperidyl)1,2,3,4-butanetetracarboxylate, tetrakis(2,2,6,6-tetramethyl-4-piperidyl)1,2,3,4-butanetetracarboxylate, bis(1,2,2,6,6-pentamethyl-4-piperidyl)sebacate, bis(2,2,6,6-tetramethyl-4-piperidyl)sebacate, bis(1-undecanoxy-2,2,6,6-tetramethylpiperidin-4-yl) carbonate, 1,2,2,6,6-pentamethyl-4-piperidyl methacrylate, and 2,2,6,6-tetramethyl-4-piperidyl methacrylate. As the light stabilizer, a bis(1-undecanoxy-2,2,6,6-tetramethylpiperidine-4-yl)carbonate is preferably used.

As the light stabilizer, a commercially available product can also be used. Examples of commercially available products of the light stabilizer include, for example, ADK STAB LA-81 (bis(1-undecanoxy-2,2,6,6-tetramethylpiperidine-4-yl)carbonate, manufactured by ADEKA CORPORATION).

The light stabilizers may be used alone or in combination of two or more.

The content ratio of the light stabilizer is, for example, 0.1 parts by mass or more, preferably 0.5 parts by mass or more, and also, for example, 5 parts by mass or less, preferably 2 parts by mass or less with respect to 100 parts by mass of the epoxy resin.

Furthermore, the content ratio of the light stabilizer is, for example, 0.05% by mass or more, preferably 0.25% by mass or more, and also, for example, 2.5% by mass or less, preferably 1% by mass or less with respect to the encapsulatable material for a display device.

Examples of the antioxidant include a hindered phenol antioxidant and a phosphite antioxidant.

Examples of the hindered phenol antioxidant include, for example, 1,3,5-tris(3,5-di-t-butyl-4-hydroxybenzyl)-1,3,5-triazine-2,4,6(1H,3H,5H)-trione, 1,1,3-tris-(2′-methyl-4′-hydroxy-5′-t-butylphenyl)-butane, stearyl 3-(3,5-di-t-butyl-4-hydroxyphenyl) propionate, pentaerythritol tetrakis[3-(3,5-di-tert-butyl-4-hydroxyphenyl)propionate, and 3,9-bis[2-[3-(3-t-butyl-4-hydroxy-5-methylphenyl) propionyloxy]-1,1-dimethylethyl]-2,4,8,10-tetraoxaspiro[5.5]undecane. As the hindered phenol antioxidant, preferably, pentaerythritol tetrakis[3-(3,5-di-tert-butyl-4-hydroxyphenyl)propionate is used.

Examples of the phosphite antioxidant include tris(2-ethylhexyl)phosphite, isodecyl diphenyl phosphite, trilauryl phosphite, tris (tridecyl) phosphite, and tri(stearyl) phosphite. As the phosphite antioxidant, isodecyl diphenyl phosphite is preferably used.

The content ratio of the antioxidant is, for example, 1 part by mass or more, and also, for example, 10 parts by mass or less, preferably 5 parts by mass or less with respect to 100 parts by mass of the epoxy resin.

Furthermore, the content ratio of the antioxidant is, for example, 0.5% by mass or more, and also, for example, 5% by mass or less, preferably 2.5% by mass or less with respect to the encapsulatable material for a display device.

The antioxidants may be used alone or in combination of two or more. Preferably, a hindered phenol antioxidant and a phosphite antioxidant are used in combination from the viewpoint of further suppressing the discoloration of the cured product under high temperature and high humidity.

When a hindered phenol antioxidant and a phosphite antioxidant are used in combination as an antioxidant, the content ratio of the hindered phenol antioxidant is, for example, 30 parts by mass or more, preferably 40 parts by mass or more, and also, for example, 70 parts by mass or less, preferably 60 parts by mass or less with respect to 100 parts by mass of the total amount of the hindered phenol antioxidant and the phosphite antioxidant. Furthermore, the content ratio of the phosphite antioxidant is, for example, 30 parts by mass or more, preferably 40 parts by mass or more, and also, for example, 70 parts by mass or less, preferably 60 parts by mass or less with respect to 100 parts by mass of the total amount of the hindered phenol antioxidant and the phosphite antioxidant.

### <Preparation of Encapsulatable Material for Display Device>

To prepare the encapsulatable material for a display device, an epoxy resin, a thermal acid initiator, a phosphor, and another component to be blended if necessary are mixed.

Specifically, first, an epoxy resin, a thermal acid initiator, and another component to be blended if necessary are mixed to prepare a mixture.

Next, the mixture and a phosphor are mixed. In this manner, an encapsulatable material for a display device is prepared.

The encapsulatable material for a display device can also be diluted with a known solvent to form a varnish. In such a case, the solid content concentration of the varnish of the encapsulatable material for a display device is, for example, 10% by mass or more, and also, for example, 70% by mass or less.

Then, in the encapsulatable material for a display device, the amount of fluorine ions measured by a test to be described later is 100 ppm or less, preferably 50 ppm or less, more preferably 20 ppm or less, and usually 1 ppm or more.

In detail, in the test, the components other than the phosphor is blended to prepare a mixture. Then, the mixture having a thickness of 100 μm is applied to a polyethylene terephthalate film using an applicator, and cured to obtain a cured product. Then, the cured product is peeled from the polyethylene terephthalate film, and the cured product is put into a heat-resistant container made of polytetrafluoroethylene, and 5 mL of ultrapure water is also added thereto, and the heat-resistant container is sealed. Then, the heat-resistant container is placed in a dryer and heated at 100° C. for 20 hours to obtain extracted water extracted from the cured product. The heat resistant container is then cooled to 25° C., and the extracted water is collected. Then, the extracted water is diluted, and the amount of the fluorine ions of the extracted water is quantitatively determined by ion chromatography.

When the above-described amount of the fluorine ions is the above-described upper limit or less, the discoloration of the cured product can be suppressed under high temperature and high humidity.

When the above-described amount of the fluorine ions exceeds the above-described upper limit, the discoloration of the cured product cannot be suppressed under high temperature and high humidity.

Furthermore, in the encapsulatable material for a display device, a color difference measured by a color difference test described later is, for example, 5.0 or less, preferably 4.0 or less, more preferably 3.0 or less, even more preferably 2.0 or less, and, from the viewpoint of further suppressing the discoloration of the cured product, particularly preferably 1.1 or less.

Then, since such an encapsulatable material for a display device can suppress the discoloration of the cured product under high temperature and high humidity, it can be suitably used as an encapsulatable material for encapsulating an optical element.

### <Encapsulating Material>

The encapsulating material includes a cured product of the above-described encapsulatable material for a display device.

In order to cure the encapsulatable material for a display device, the encapsulatable material for a display device is heated.

As the heating conditions, the heating temperature is, for example, 60° C. or more, preferably 100° C. or more, and also, for example, 150° C. or less. Furthermore, the heating time is, for example, 1 minute or more, preferably 30 minutes or more, and also, for example, 120 minutes or less.

In this manner, the encapsulatable material for a display device is cured, thereby obtaining a cured product of the encapsulatable material for a display device.

The cured product of the encapsulatable material for a display device preferably has transparency. Specifically, the total luminous transmittance (in conformity with JIS K 7361-1) of the cured product of the encapsulatable material for a display device is, for example, 80% or more, preferably 85% or more, more preferably 90% or more, even more preferably 95% or more, and also, for example, 100% or less.

Then, such an encapsulating material can be suitably used for manufacturing an organic EL display and an LED display.

That is, the organic EL display includes an organic EL device and the encapsulating material. Specifically, the organic EL display includes an organic EL device and the encapsulating material covering a surface of the organic EL device. Furthermore, the LED display includes an LED and the encapsulating material. In detail, the LED display includes an LED and the encapsulating material covering a surface of the LED.

### 2. Second Invention

In the second invention, the encapsulatable material for a display device includes an epoxy resin, a thermal acid initiator, and a phosphor. Furthermore, the thermal initiator is a quaternary ammonium salt having B(C₆F₅)₄— as the counter anion.

The encapsulatable material for a display device contains a thermal initiator that is a quaternary ammonium salt having B(C₆F₅)₄— as the counter anion, and thus can suppress the discoloration of the cured product under high temperature and high humidity.

Furthermore, the content ratio of the thermal acid initiator is the same as the content ratio of the thermal acid initiator of the above-described first invention.

Furthermore, the epoxy resin and the phosphor are the same as the epoxy resin and the thermal acid initiator described as an example in the above-described first invention. Furthermore, the content ratios thereof are the same as the content ratios described as examples in the above-described first invention.

Furthermore, the encapsulatable material for a display device includes, if necessary, another component described as an example in the above-described first invention. Furthermore, the content ratio thereof is the same as the content ratio described as an example in the above-described first invention.

Then, the encapsulatable material for a display device can be prepared by the same method as in the above-described first invention. Furthermore, by curing the encapsulatable material for a display device by the same method as in the above-described first invention, it is possible to manufacture the same cured product (encapsulating material) of the encapsulatable material for a display device as in the above-described first invention. Furthermore, by using the encapsulating material, it is possible to manufacture the same organic EL display and LED display as in the above-described first invention.

### 3. Operations and Effects

In the encapsulatable material for a display device, the amount of fluorine ions measured by a predetermined test is 100 ppm or less, or in the encapsulatable material for a display device, the thermal acid initiator is a quaternary ammonium salt having B(C₆F₅)₄— as the counter anion. Therefore, it is possible to suppress the discoloration of the cured product under high temperature and high humidity.

In detail, a cured product of an encapsulatable material for a display device containing a phosphor has a problem that the cured product is discolored by the fluorine ions generated from the thermal acid initiator under high temperature and high humidity.

In particular, from the viewpoint of improving heat resistance, water resistance, and adhesion, an epoxy resin is selected instead of a silicone resin. When an epoxy resin is selected, however, the above-described discoloration easily occurs.

On the other hand, in the encapsulatable material for a display device, the amount of fluorine ions measured by a predetermined test is 100 ppm or less, or in the encapsulatable material for a display device, the thermal acid initiator is a quaternary ammonium salt having B(C₆F₅)₄— as the counter anion. Thus, the amount of fluorine ions generated from the thermal acid initiator is suppressed. Therefore, even when an epoxy resin is contained, the discoloration of the cured product can be suppressed under high temperature and high humidity.

### EXAMPLES

Next, the present invention is described based on Examples and Comparative Examples. The present invention is, however, not limited to them. The “parts” and “%” are based on mass unless otherwise specified. The specific numeral values used in the description below, such as mixing ratios (content ratios), physical property values, and parameters, can be replaced with the corresponding mixing ratios (content ratios), physical property values, and parameters in the above-described “DESCRIPTION OF THE EMBODIMENTS”, including the upper limit values (numeral values defined with “or less”, and “less than”) or the lower limit values (numeral values defined with “or more”, and “more than”).

### <Details of Components>

The trade names and abbreviations of the components used in each of Examples and Comparative Examples are detailed.
YL983U: Bisphenol F-type epoxy-resin, manufactured by Mitsubishi Chemical Corporation
EP-4010S: Propylene oxide adduct of bisphenol A type epoxy resin, manufactured by ADEKA CORPORATION
YX8000: Hydrogenated bisphenol A diglycidyl ether, manufactured by Mitsubishi Chemical Corporation
CEL2021P: 3′,4′-epoxycyclohexylmethyl(3,4-epoxy)cyclohexanecarboxylate, an ECH structure-containing epoxy resin represented by the above-described general formula (4), trade name “Celloxide 2021P”, epoxy equivalent: 128 to 145 g/eq., manufactured by Daicel Corporation
X-40-2669: Straight-chain siloxane skeleton-containing epoxy resin (a compound represented by the above-described formula (6)), manufactured by Shin-Etsu Chemical Co., Ltd.
X-40-2678: Cyclic siloxane skeleton-containing epoxy resin (a compound represented by the above-described formula (8)), manufactured by Shin-Etsu Chemical Co., Ltd.
KR-470: Cyclic siloxane skeleton-containing epoxy resin (a compound represented by the above-described formula (9)), manufactured by Shin-Etsu Chemical Co., Ltd.
YL-9028: Ladder-like siloxane skeleton-containing epoxy resin (a compound represented by the above-described formula (10)), manufactured by Mitsubishi Chemical Corporation
CXC-1821: Quaternary ammonium salt having B(C₆F₅)₄— as the counter anion, manufactured by King industry
CXC-1733: Quaternary ammonium salt having SbF₆— as the counter anion, manufactured by King industry
OXT-221: 3-ethyl-3{[(3-ethyloxetan-3-yl)methoxy]methyl}oxetane, trade name“ARON OXETANE OXT-221”, manufactured by TOAGOSEI CO., LTD.
LA-81: Bis(1-undecanoxy-2,2,6,6-tetramethylpiperidine-4-yl)carbonate, trade name “ADK STAB LA-81”, manufactured by ADEKA CORPORATION
AO-60: Hindered phenol antioxidant (pentaerythritol tetrakis[3-(3,5-di-tert-butyl-4-hydroxyphenyl)propionate], manufactured by ADEKA CORPORATION
135A: Phosphite antioxidant (isodecyl diphenyl phosphite), manufactured by ADEKA CORPORATION

### Preparation of Encapsulatable Material for Display Device

### Examples 1 to 13 and Comparative Examples 1 to 5

Based on the formulations shown in Tables 1 and 2, an epoxy resin, a thermal acid initiator, and another component were mixed with a magnetic stirrer. In this manner, a mixture was prepared.

Next, the mixture and a phosphor (sulfur-containing phosphor) were blended so that mixture/phosphor=1/1 (mass ratio) held, and mixed in a V-Mini300 manufactured by EME Co., Ltd., at 1600 revolutions for 1 minute. In this manner, an encapsulatable material for a display device was prepared. The unit of the numerical value of each component shown in Tables 1 and 2 is part by mass.

### <Evaluations>

### [Amount of Fluorine Ions]

Based on the formulation of each of Examples and Comparative Examples, a mixture consisting of the components other than the phosphor was prepared. Then, the above-described mixture (the mixture consisting of the components other than the phosphor) having a thickness of 100 μm was applied to a polyethylene terephthalate film using an applicator, and cured to obtain a cured product. Then, the cured product was peeled from the polyethylene terephthalate film, and the cured product was put into a heat-resistant container made of polytetrafluoroethylene, and 5 mL of ultrapure water was also added thereto, and the heat-resistant container was sealed. Then, the heat-resistant container was placed in a dryer and heated at 100° C. for 20 hours to obtain extracted water extracted from the cured product. The heat-resistant container was then cooled to 25° C., and the extracted water was collected. Then, the extracted water was diluted, and then the amount of the fluorine ions of the extracted water was quantitatively determined by an ion chromatography method (measuring device: ICS-3000 (manufactured by Thermo Fisher Scientific Inc.)). The results are shown in Tables 1 and 2.

### [Color Difference Test]

The encapsulatable material for a display device of each of Examples and Comparative Examples was applied to a glass plate to form a coating film. Then, the coating film was heated at 120° C. for 60 minutes to cure the coating film to obtain a cured product (a thickness of 100 μm).

Then, an a* (initial stage) of the cured product was measured using a color difference meter (SE2000, manufactured by NIPPON DENSHOKU INDUSTRIES Co., Ltd.). The cured product was then stored at 85° C. and 85% humidity for 2 days. An a* (2 days after) was then measured based on the same procedure. The cured product was then stored at 85° C. and 85% humidity for 5 days. An a* (7 days after) was then measured based on the same procedure. It can be seen that the smaller the color difference (|a* (Initial))−|a* (7 days after)|) is, the more the discoloration can be suppressed under high temperature and high humidity. The results are shown in Tables 1 and 2.

### <Consideration>

In Examples 1 to 13 in which the above-described amount of fluorine ions is 100 ppm or less, the color-difference is smaller than that of Comparative Examples 1 to 5 in which the amount of fluorine ions exceeds 100 ppm. From this, it can be seen that, if the amount of fluorine ions is 100 ppm or less, discoloration can be suppressed under high temperature and high humidity.

TABLE 1

| Ex. No. | | | | Ex. 1 | Ex. 2 | Ex. 3 | Ex. 4 | Ex. 5 | Ex. 6 | Ex. 7 | Ex. 8 | Ex. 9 |
|---|---|---|---|---|---|---|---|---|---|---|---|---|
| Epoxy | Siloxane | Siloxane skeleton-free | YL983U | 100 | — | — | — | — | 100 | — | — | — |
| resin | skeleton-free | aromatic epoxy resin | EP-4010S | — | — | 100 | — | — | — | — | — | — |
| | epoxy resin | Siloxane skeleton-free | YX8000 | — | 100 | — | 50 | 50 | — | 100 | — | — |
| | | alicyclic epoxy resin | CEL2021P | — | — | — | — | 50 | — | — | — | — |
| | Siloxane | Straight-chain siloxane | X-40-2669 | — | — | — | — | — | — | — | 100 | — |
| | skeleton- | skeleton-containing epoxy resin | | | | | | | | | | |
| | containing | Cyclic siloxane skeleton- | X-40-2678 | — | — | — | — | — | — | — | — | 100 |
| | epoxy resin | containing epoxy resin | KR-470 | — | — | — | — | — | — | — | — | — |
| | | Ladder-like siloxane | YL-9028 | — | — | — | — | — | — | — | — | — |
| | | skeleton-containing epoxy resin | | | | | | | | | | |
| Thermal acid initiator | | | CXC-1821 | 2 | 2 | 2 | 2 | 2 | 2 | 2 | 2 | 2 |
| | | | CXC-1733 | — | — | — | — | — | — | — | — | — |
| Other | Oxetane compound | | OXT-221 | — | — | — | 50 | — | — | — | — | — |
| components | Additives | Light stabilizer | LA-81 | — | — | — | — | — | 1 | 1 | 1 | 1 |

| | | | | | | | | | | | |
|---|---|---|---|---|---|---|---|---|---|---|---|
| Antioxidant | Hindered phenol | AO-60 | — | — | — | — | — | 1 | 1 | 1 | 1 |
| | antioxidant | | | | | | | | | | |
| | Phosphite antioxidant | 135A | — | — | — | — | — | 1 | 1 | 1 | 1 |

| Evaluation | Amount of fluorine ions (ppm) | | 10 | 10 | 12 | 10 | 12 | 10 | 10 | 10 | 10 |
|---|---|---|---|---|---|---|---|---|---|---|---|
| | Color difference test | a*(initial stage) | −28.4 | −29.7 | −30.3 | −29.6 | −28.6 | −28.5 | −28.7 | −27.6 | −28.7 |

| | | | | | | | | | |
|---|---|---|---|---|---|---|---|---|---|
| a*(2 days after) | −26.8 | −28.2 | −28.2 | −26.6 | −25.6 | −27.9 | −28.2 | −26.6 | −28.2 |
| a*(7 days after) | −26.6 | −27.0 | −26.8 | −25.7 | −24.3 | −27.5 | −27.5 | −26.6 | −27.6 |
| Color difference | 1.8 | 2.7 | 3.5 | 3.9 | 4.3 | 1.0 | 1.2 | 1.0 | 1.1 |

TABLE 2

| | | | | Ex.▪ Comp. No. | | | | | | | | |
|---|---|---|---|---|---|---|---|---|---|---|---|---|
| | | | | Ex. | Ex. | Ex. | Ex. | Comp. | Comp. | Comp. | Comp. | Comp. |
| | | | | 10 | 11 | 12 | 13 | 1 | 2 | 3 | 4 | 5 |
| Epoxy | Siloxane | Siloxane skeleton-free | YL983U | — | — | 100 | 100 | 100 | — | — | — | — |
| resin | skeleton- | aromatic epoxy resin | EP-4010S | — | — | — | — | — | — | 100 | 50 | 50 |
| | free epoxy | Siloxane skeleton-free | YX8000 | — | — | — | — | — | 100 | — | — | — |
| | resin | alicyclic epoxy resin | CEL2021P | — | — | — | — | — | — | — | — | 50 |
| | Siloxane | Straight-chain siloxane | X-40-2669 | — | — | — | — | — | — | — | — | — |
| | skeleton- | skeleton-containing | | | | | | | | | | |
| | containing | epoxy resin | | | | | | | | | | |
| | epoxy | Cyclic siloxane skeleton- | X-40-2678 | — | — | — | — | — | — | — | — | — |
| | resin | containing epoxy resin | KR-470 | — | 100 | — | — | — | — | — | — | — |
| | | Ladder-like siloxane | YL-9028 | 100 | — | — | — | — | — | — | — | — |
| | | skeleton-containing | | | | | | | | | | |
| | | epoxy resin | | | | | | | | | | |
| Thermal acid initiator | | | CXC-1821 | 2 | 2 | 2 | 2 | — | — | — | — | — |
| | | | CXC-1733 | — | — | — | — | 2 | 2 | 2 | 2 | 2 |
| Other | Oxetane compound | | OXT-221 | — | — | — | — | — | — | — | 50 | — |
| components | Additives | Light stabilizer | LA-81 | 1 | 1 | 1 | 1 | — | — | — | — | — |

| | | | | | | | | | | | |
|---|---|---|---|---|---|---|---|---|---|---|---|
| Antioxidant | Hindered | AO-60 | 1 | 1 | 1 | — | — | — | — | — | — |
| | phenol | | | | | | | | | | |
| | antioxidant | | | | | | | | | | |
| | Phosphite | 135A | 1 | 1 | — | 1 | — | — | — | — | — |
| | antioxidant | | | | | | | | | | |

| Evaluation | Amount of fluorine ions (ppm) | | 10 | 10 | 10 | 10 | 2800 | 2800 | 2850 | 2750 | 2900 |
|---|---|---|---|---|---|---|---|---|---|---|---|
| | Color difference test | a*(initial | −27.6 | −27.6 | −27.7 | −27.8 | −27.5 | −27.5 | −27.6 | −29.7 | −30.3 |
| | | stage) | | | | | | | | | |

| | | | | | | | | | |
|---|---|---|---|---|---|---|---|---|---|
| a*(2 days | −26.5 | −26.5 | −26.8 | −26.8 | −15.0 | −21.0 | −17.3 | −14.3 | −18.8 |
| after) | | | | | | | | | |
| a*(7 days | −26.5 | −26.5 | −26.6 | −26.5 | −10.0 | −15.0 | −2.6 | −5.0 | −10.0 |
| after) | | | | | | | | | |
| Color | 1.1 | 1.1 | 1.1 | 1.3 | 17.5 | 12.5 | 25.0 | 24.7 | 20.3 |
| difference | | | | | | | | | |

While the illustrative embodiments of the present invention are provided in the above-described description, such is for illustrative purpose only and it is not to be construed as limiting in any manner. Modification and variation of the present invention that will be obvious to those skilled in the art is to be covered by the following claims.

### INDUSTRIAL APPLICABILITY

The encapsulatable material for a display device and the encapsulating material of the present invention are suitably used, for example, for an organic EL display and an LED display. The organic EL display and LED display of the present invention are suitably used for manufacturing display devices.

1. An encapsulatable material for a display device comprising: an epoxy resin; a thermal acid initiator; and a phosphor,
wherein an amount of fluorine ions measured by the following test is 100 ppm or less.
<Test>
The Components other than the phosphor are blended to prepare a mixture. Then, the mixture having a thickness of 100 μm is applied to a polyethylene terephthalate film, and cured to obtain a cured product. Then, the cured product is peeled from the polyethylene terephthalate film, and the cured product is put into a heat-resistant container made of polytetrafluoroethylene, and 5 mL of ultrapure water is also added thereto, and the heat-resistant container is sealed. Then, the heat-resistant container is placed in a dryer and heated at 100° C. for 20 hours to obtain extracted water extracted from the cured product. The heat-resistant container is then cooled to 25° C., and the extracted water is collected. Then, the extracted water is diluted, and the fluorine ions of the extracted water is quantitatively determined by an ion chromatography method.

2. The encapsulatable material for a display device according to claim 1,
wherein the phosphor is a sulfur-containing phosphor.

3. The encapsulatable material for a display device according to claim 1,
wherein the thermal acid initiator contains a fluorine atom.

4. The encapsulatable material for a display device according to claim 1,
wherein the thermal acid initiator is a quaternary ammonium salt having B(C₆F₅)₄— as a counter anion.

5. The encapsulatable material for a display device according to claim 1, further comprising: an antioxidant.

6. The encapsulatable material for a display device according to claim 5,
wherein the antioxidant includes a hindered phenol antioxidant and a phosphite antioxidant.

7. An encapsulatable material for a display device comprising: an epoxy resin; a thermal acid initiator; and a phosphor,
wherein the thermal acid initiator is a quaternary ammonium salt having B(C₆F₅)₄— as a counter anion.

8. The encapsulatable material for a display device according to claim 7, further comprising: an antioxidant.

9. The encapsulatable material for a display device according to claim 1,
wherein a color difference in the following color difference test is 1.1 or less.
Color difference test: The encapsulatable material for a display device is applied to a glass plate to form a coating film. Then, the coating film is heated at 120° C. for 60 minutes, and the coating film is cured to obtain a cured product having a thickness of 100 μm. Then, an a* (initial stage) of the cured product is measured using a color difference meter. The cured product is then stored at 85° C. and 85% humidity for 7 days, and an a* (after 7 days) is measured. (|a* (initial stage)|−|a* (after 7 days)|) is determined as the color difference.

10. An encapsulating material comprising: a cured product of the encapsulatable material for a display device according to claim 1.

11. An organic EL display comprising: the encapsulating material according to claim 10.

12. An LED display comprising: the encapsulating material according to claim 10.
